(19) United States
(12) Patent Application Publication
(10) Pub. No.: US 2006/0071717 A1
(43) Pub. Date: Apr. 6, 2006

(54) Prescaler for a phase-locked loop circuit

(76) Inventors: Abdelghani El-Kacimi, Freising (DE); Harald Sandner, Marzling (DE)

Correspondence Address: TEXAS INSTRUMENTS INCORPORATED, P O BOX 655474, M/S 3999, DALLAS, TX, 75265, US

(21) Appl. No.: 11/219,989

(22) Filed: Sep. 6, 2005

(30) Foreign Application Priority Data
Sep. 6, 2004 (DE) 10 2004 043 022.5

(51) Int. Cl. H03L 7/00

(52) U.S. Cl. 331/16

(57) ABSTRACT

A prescaler (10; 110) for use in a phase locked loop circuit, having a signal input (12; 112) receiving a digital input signal (SIG_IN) and a signal output (14; 114) supplying a digital output signal (SIG_OUT). A phase shifter (20; 120) receives an input signal from the signal input (12; 112), and supplies a set of n metasignals (METAₖ; META_{I}, META_{Q}, META_{IN}, META_{QN}) each having a relative phase shift of 2π/n with respect to another one of these metasignals. A phase selector (22; 122) has n inputs (34; 134I, 134Q, 134IN, 134QN) to each of which is applied a different one of the metasignals (METAₖ; META_{I}, MET_{AQ}, META_{IN}, META_{QN}) and an output (36; 136) that supplies a selected one of the metasignals. A final frequency divider (26; 126) has an input (70; 170) connected to the output (36; 136) of the phase selector (22; 122) and an output (72; 172) forming the signal output (14; 114) of the prescaler. A control circuit (60; 160) is associated with the phase selector (22; 122) and controls the phase selector so that the output (36; 136) of the phase selector is switched between different metasignals only when these different metasignals are in the same logical state, thereby avoiding the occurrence of glitches that would cause a frequency divider to miscount.

### TECHNICAL FIELD OF THE INVENTION

The present invention relates to a prescaler for use in a phase locked loop circuit.

### BACKGROUND OF THE INVENTION

Phase locked loop circuits with a prescaler are well-known, for example from the book “Theorie und Anwendungen des Phase-locked Loops” by Roland West, VDE Verlag Germany 1993, for the use in various applications such as frequency synthesizers for instance. With a prescaler having dividing factors of V and V+1, where V may be any natural number, it is possible to tune a synthesizer through a set of equidistant frequencies over a range which depends on the dividing factors of frequency dividers present in the phase locked loop. However, the frequency stability of the output signal highly depends on the accuracy of the dividing factors in the prescaler.

### SUMMARY OF THE INVENTION

The invention provides a prescaler with high accuracy and reliability. In general, a prescaler for use in a digital phase locked loop circuit is provided, which has a signal input receiving a digital input signal and a signal output supplying a digital output signal. The prescaler includes a phase shifter receiving the input signal from the signal input, and supplying a set of n metasignals, each having a relative phase shift of 2π/n with respect to another one of the metasignals. The prescaler further includes a phase selector, having n inputs to each of which is applied a different one of the metasignals and an output supplying a selected one of the metasignals, a frequency divider, having an input connected to the output of the phase selector and an output forming the signal output of the prescaler, and a control circuit associated with the phase selector and controlling the phase selector so that the output of the phase selector is switched between different metasignals only when the different metasignals are in the same logical state.

This configuration ensures an accurate switching of the multiplexer from one metasignal to another metasignal without producing glitches which would cause a frequency divider to miscount.

In some embodiments, the phase selector can operate in a first mode to select continuously a particular one of the metasignals for propagation to its output.

In some embodiments, the prescaler can operate in a second mode in which the signal output is connected to a clock input of the control circuit and the control circuit controls the phase selector to cyclically select each of the metasignals under control of the output signal.

In embodiments including the first mode, a digital input signal is divided by a first dividing factor, and in embodiments also including the second mode, the input signal is divided by a second dividing factor different from the first dividing factor.

In some embodiments of the invention, the prescaler comprises an initial frequency divider receiving an input signal from the signal input and dividing the input signal by an integer dividing factor p. When the digital input signal is divided, the following stages of the prescaler do not have to be operated at the maximum frequency. Therefore, they can advantageously be biased at a lower current, thus reducing the overall power requirements.

These and other aspects and features of the invention will be apparent to those skilled in the art from the following detailed description of the invention, taken together with the accompanying drawings.

### BRIEF DESCRIPTION OF THE DRAWINGS

FIG. 1 shows a block diagram of a prescaler according to the invention.

FIG. 2 shows a diagram illustrating the problems involved with the occurrence of a glitch.

FIG. 3 shows a more detailed block diagram of the prescaler of FIG. 1.

FIG. 4 shows a diagram illustrating signals in a phase selector when the prescaler of FIG. 1 transits from a first operation mode into a second operation mode.

FIG. 5 shows a diagram illustrating the signals in the phase selector when the prescaler of FIG. 1 is operating in a second mode.

FIG. 6 shows a diagram illustrating signals in the phase selector when switching from one phase to another during operation in the second mode.

### DETAILED DESCRIPTION OF THE PREFERRED EMBODIMENT

The making and use of the various embodiments are discussed below in detail. However, it should be appreciated that the present invention provides many applicable inventive concepts which can be embodied in a wide variety of specific contexts. The specific embodiments discussed are merely illustrative of specific ways to make and use the invention, and do not limit the scope of the invention.

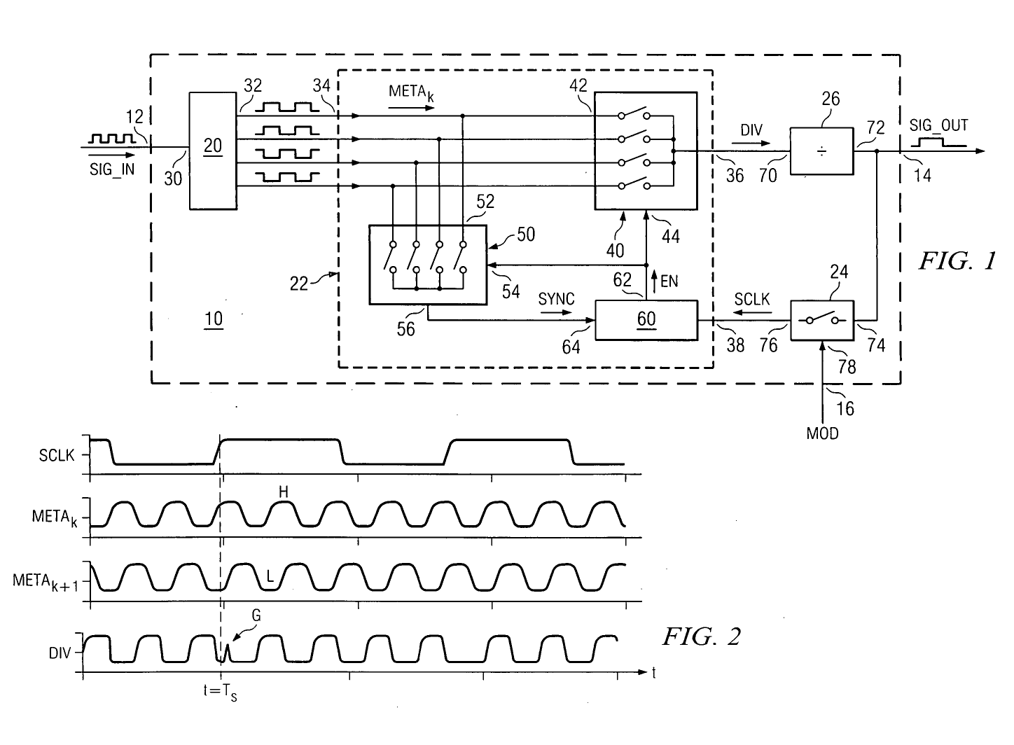

Referring now to FIG. 1, there is shown a prescaler 10 in accordance with a preferred embodiment of the present invention. The prescaler 10 includes a digital signal input 12, a digital signal output 14 and a mode select input 16. The prescaler 10 includes a phase shifter 20, a phase selector 22, a mode select circuit 24 and a final frequency divider 26. The phase shifter 20 has an input 30 connected to the digital signal input 12 of the prescaler 10 and a plurality of metasignal outputs 32. The phase selector 22 has a plurality of metasignal inputs 34 connected to the metasignal outputs 32 of the phase shifter 20, an intermediate signal output 36 and a selecting clock input 38. The phase selector 22 includes a signal multiplexer 40, a clock sync multiplexer 50 and a control circuit 60. The signal multiplexer 40 has a plurality of source inputs 42 connected to the metasignal inputs 34 of the phase selector 22, a select input 44 and an output representing the intermediate signal output 36 of the phase selector 22. The clock sync multiplexer 50 has a plurality of source inputs 52 also connected to the metasignal inputs 34 of the phase selector 22, a select input 54 and a clock sync signal output 56.

The control circuit 60 has an input representing the selecting clock input 38 of the phase selector 22, a control output 62 connected to the select input 44 of the signal multiplexer 40 and to the select input 54 of the clock sync multiplexer 50, and a clock sync signal input 64 connected to the clock sync signal output 56 of the clock sync multiplexer 50. The control circuit 60 controls the signal multiplexer 40 via the select input 44 to select one of the signals connected to the signal inputs 42 and switch it through to the intermediate signal output 36.

The final frequency divider 26 has an intermediate signal input 70 connected to the intermediate signal output 36 of the phase selector 22 and a signal output 72 forming the digital signal output 14 of the prescaler 10.

The mode select circuit 24 has a clock signal input 74 connected to the digital signal output 14 of the prescaler 10, a clock signal output 76 connected to the selecting clock input 38 of the phase selector 22 and a mode select input 78 representing the mode select input 16 of the prescaler 10.

The prescaler 10 can operate in a first mode in which a digital input signal SIG_IN that is fed to the digital signal input 12 is divided by a first dividing factor V (V being a natural number), and a second mode in which the input signal is divided by a second dividing factor V′ different from the first dividing factor V.

In the following, the operation of the prescaler 10 in the first mode is explained in detail.

The digital input signal SIG_IN is received at the input 12 of the phase shifter 20 which splits it into a set of n metasignals METAₖ provided at the metasignal outputs 32, these metasignals having a relative phase shift of 2π/n, where k and n are natural numbers and k=1 to n.

In the first mode, the control circuit 60 controls the signal multiplexer 40 with control signals EN at the control output 62 to statically select one of the metasignals METAₖ and provide it as intermediate signal DIV at the intermediate signal output 36 of the phase selector 22.

The final frequency divider 26, receives the intermediate signal DIV via the intermediate signal input 170, divides it by a dividing factor q and supplies an output signal SIG_OUT at the signal output 14. The dividing factor of the prescaler 10 in the first mode is therefore q.

In the following, the operation of the prescaler 10 in the second mode is explained in detail.

The prescaler 10 can be switched into the second mode by a mode select command MOD at the mode select input 16. From the block diagram in FIG. 1, it is apparent that the output signal SIG_OUT from the output 72 of the final frequency divider 26 is received at the clock signal input 74 of the mode select circuit 24. In the second mode, the mode select circuit 24 switches through the output signal from the final frequency divider 26 to the clock signal output 76 as a selecting clock signal SCLK.

In the phase selector 22, the selecting clock signal SCLK is used to trigger the operation of the control circuit 60. In the second mode, the control circuit 60 controls the signal multiplexer 40 with the control signals EN via the select input 44 to cyclically switch through the metasignals METAₖ connected to the signal inputs 42. With each flank of the selecting clock signal SCLK, the signal multiplexer is controlled to switch from one metasignal METAₖ to the next metasignal METAₖ+1. This procedure, which is known as phase swallowing, causes a phase shift of 2π/n in the intermediate signal DIV each q periods of the input signal SIG-IN since the dividing factor of the final frequency divider is q. The dividing factor of the prescaler 10 in the second mode is therefore q+1/n.

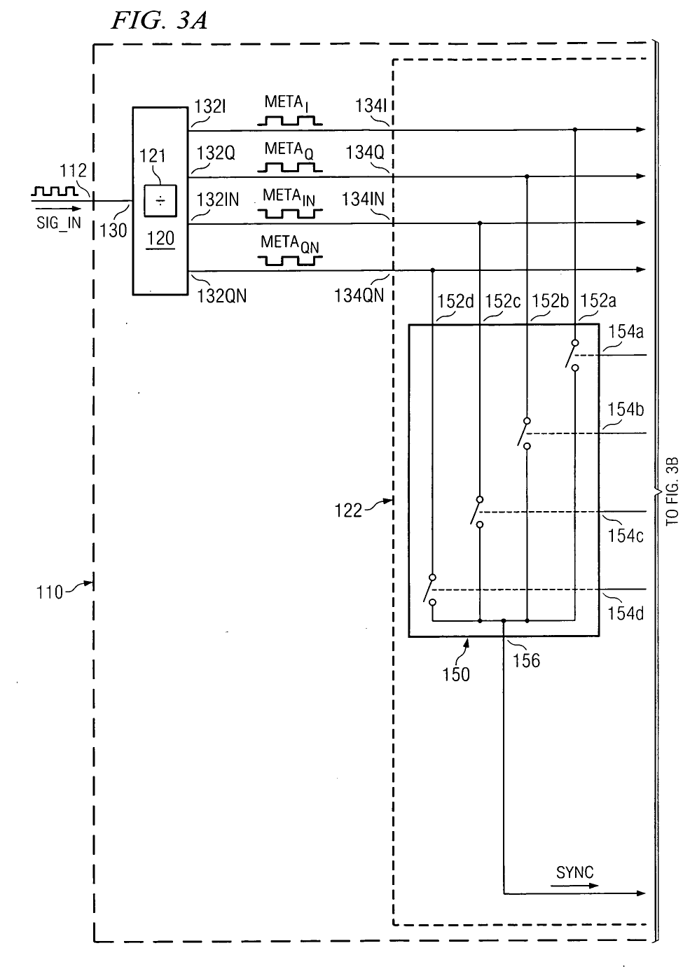

However, if switching from one metasignal METAk to the next metasignal METAₖ+1 is not perfectly timed, a glitch may occur. This is illustrated in FIG. 2 where a switching event occurs at moment in time t=Tₛ. In this moment, the metasignal METAₖ has already risen from the logical low state to the logical high state, while metasignal METAₖ+1 is still in the logical low state and will rise only a short time after the switching has completed. Consequently, a glitch G occurs in the intermediate signal DIV. The glitch will be misinterpreted as an extra pulse by the following final frequency divider 26 and will lead to a miscounting. As a result, the dividing factor of the prescaler 10 is distorted. This may cause severe problems in the closed loop control if the prescaler is used in a phase locked loop, for instance.

The generation of glitches is avoided, in accordance with the invention, by controlling the signal multiplexer 40 so as to switch from metasignal METAₖ to METAₖ+1 only when both are in the same logical state. In the present embodiment, this condition is fulfilled by synchronizing the selecting clock signal SCLK with the metasignals METAₖ themselves.

For this purpose, the clock multiplexer 50 selects one out of the set of metasignals at the source inputs 52 to provide at its clock sync output 56 a clock sync signal SYNC for the control circuit 60. On the other hand, the clock multiplexer 50 itself is controlled by the control signals EN from the control circuit 60 via the select input 54 to select the appropriate one of the metasignals for synchronization of the selecting clock signal SCLK.

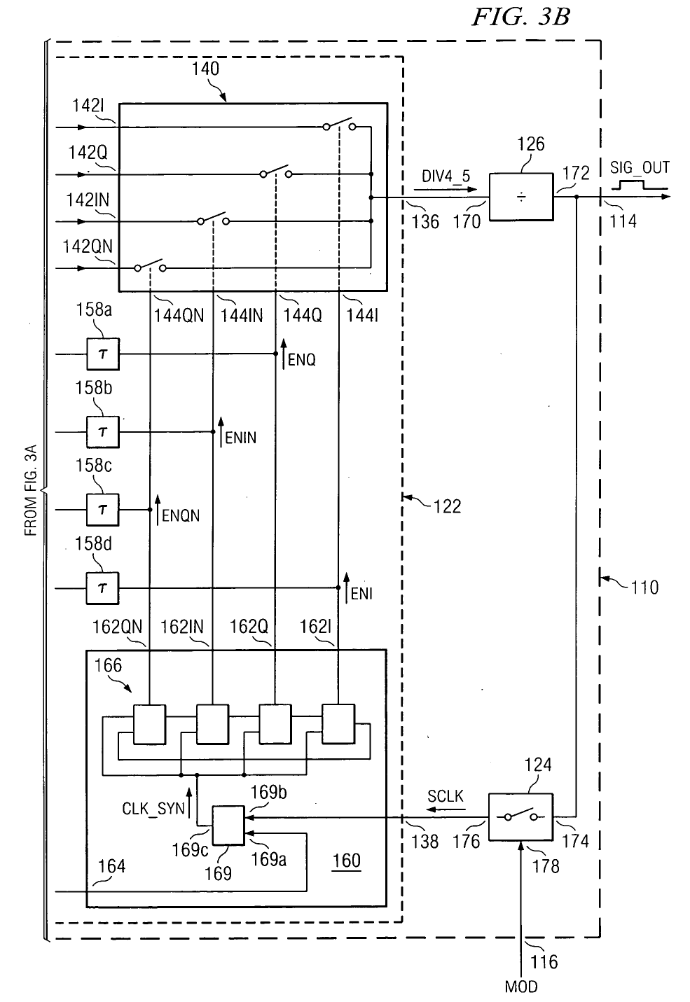

Referring now to FIG. 3, there is illustrated a more detailed implementation of a prescaler 110 according to the invention that provides a first dividing factor of v=16 and a second dividing factor of v′=17. In FIG. 3, for components already disclosed, like numerals augmented by 100 are used.

In this implementation, the phase shifter 120 includes an initial frequency divider 121 with an initial dividing factor p=4. The phase shifter 120 has a set of n=4 metasignal outputs, providing a set of four metasignals. For reasons of clarity, the metasignals will be referred to as META_{I}, META_{Q}, META_{IN} and META_{QN} and the metasignal outputs respectively have the reference numerals 132I, 132Q, 132IN, 132QN.

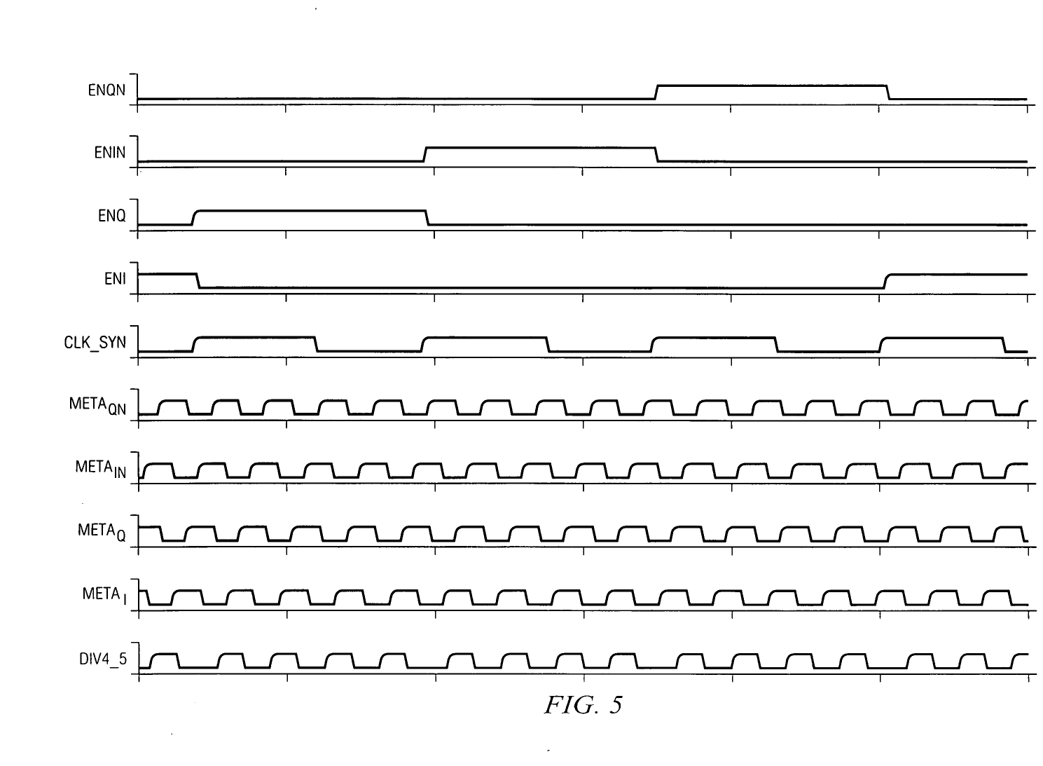

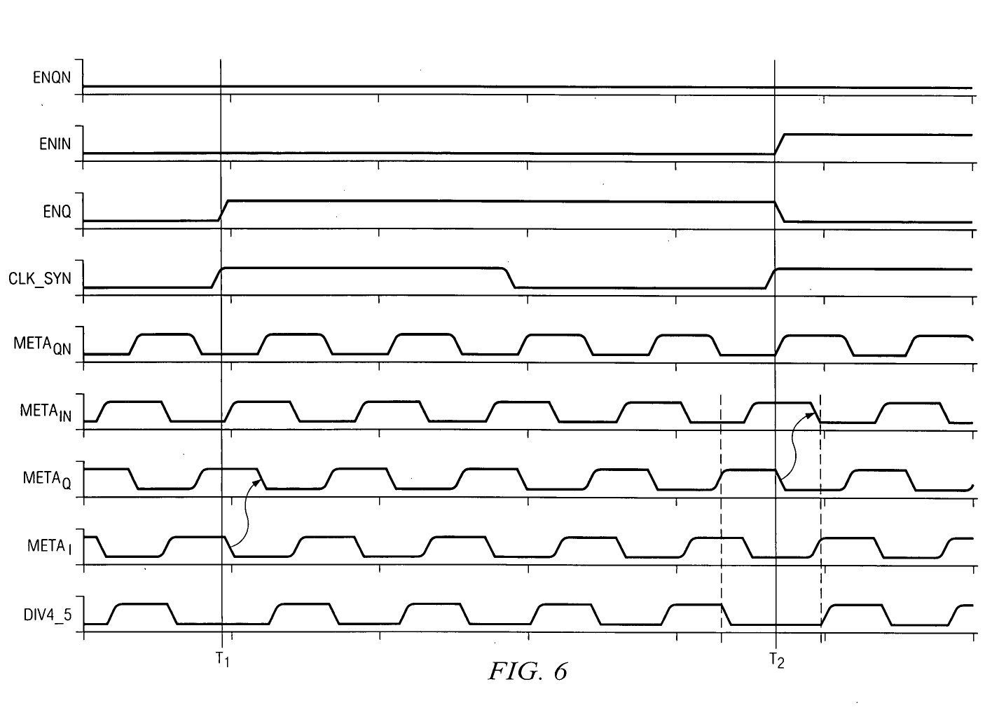

The input 112 of the prescaler 200 is supplied with a digital signal SIG_IN, for example from a voltage-controlled oscillator of a phase-locked loop circuit (not shown). The phase shifter 120 receives the digital input signal SIG_IN from the signal input 112, divides it by the initial dividing factor p=4 in the initial frequency divider 121 and provides a set of four metasignals META_{Q}, META_{I}, META_{QN} and META_{IN}. The phases of the four metasignals are equidistantly distributed over one period with a relative phase shift of 2π/n=90°. Metasignal METAI, which has a phase shift of 90° ante with respect to the metasignal META_{Q}, and metasignals META_{IN} and META_{QN} are the inverse signals to META_{I} and META_{Q} respectively, as illustrated in FIGS. 5 and 6.

The metasignals META_{I}, META_{Q}, META_{IN} and META_{QN} are supplied to the phase selector 122 which has four signal inputs 134I, 134Q, 134IN, 134QN, connected to the outputs 132I, 132Q, 132IN, 132QN of the phase shifter 120.

The signal multiplexer 140 in the phase selector 122 has four source inputs 142I, 142Q, 142IN, 142QN and four select inputs 144I, 144Q, 144IN, 144QN. Each of the source inputs is assigned to one of the select inputs, e.g. source input 142I is assigned to select input 144I. The phase selector 122 is controlled in a way that the one metasignal, e.g. META_{I}, which is connected to a specified source input, e.g. 142I, is selected to be passed to the output 136 of the phase selector 122 when a control signal is applied to the assigned select input, e.g. 144I.

The control circuit 160 in this implementation comprises a four-stage cycle shift register 166, that has four outputs which are control signal outputs 162I, 162Q, 162IN, 162QN of the control circuit 160 for providing control signals ENI, ENQ, ENIN, ENQN to the signal multiplexer 140. Upon power up of the prescaler 110, the cycle shift register 166 is preferably set into a defined state in which only one of the outputs 162I, 162Q, 162IN, 162QN has logical high state.

The control circuit 160 further comprises a trigger unit 169 that has an enable input I69a representing the clock sync input 164 of the control circuit 160, a clock input 169b representing the clock signal input 138 of the phase selector 122 and a clock output 169c for triggering the cycle shift register 166 of the control circuit 160.

The clock multiplexer 150 has four source inputs 152a, 152b, 152c, 152d, four select inputs 154a, 154b, 154c, 154d and one clock sync signal output 156. The four source inputs 152a, 152b, 152c, 152d of the clock multiplexer 150 are connected to the metasignal outputs 132I, 132Q, 132IN, 132QN of the phase shifter 120 and the select inputs 154a, 154b, 154c, 154d are connected to the control signal outputs 162I, 162Q, 162IN, 162QN, just like the select inputs of the signal multiplexer 140, but in a different order. The select inputs 154a, 154b, 154c, 154d are each provided with a delay line 158a, 158b, 158c, 158d, respectively.

In the following, the function of the prescaler 110 in the first mode will be explained in detail. In this mode, the prescaler 110 is used to divide a digital input signal SIG_IN by a dividing factor v=16.

In the first mode of operation, the select clock signal SCLK is not enabled by the mode select circuit 124, therefore the cycle shift register 166 in the control circuit 160 is not triggered, and the control signals ENI, ENQ, ENIN, ENQN are static. If it is assumed hat the control signal ENI at the signal control output 1621 of the control circuit 160 is high and the other control signals ENQ, ENIN, ENQN are low, the signal multiplexer 140 is controlled to select the metasignal META_{I} out of the plurality of metasignals to be switched through as an intermediate signal DIV4_{—}5 to the intermediate signal output 136 of the phase selector 122.

In this implementation, the final frequency divider 126 is configured with a dividing factor of q=4. So, the intermediate signal DIV4_{—}5 is further divided in the final frequency divider 126 by the final dividing factor of q=4 and the signal output 114 supplies an output signal SIG_OUT, the frequency of the output signal SIG_OUT being 1/16 of the frequency of the input signal SIG_IN. Therefore, the prescaler 110 provides a first dividing factor of v=16 when operating in the first mode.

In a second mode of operation, a second dividing factor of v′=17 is used. To switch the prescaler 110 into this second operation mode, an appropriate mode select command MOD is applied to the mode select input 116, e.g. from a phase locked loop circuit in which the prescaler 110 may be used. In a most simple implementation, the mode select circuit 124 will just switch through the output signal of the final frequency divider 126 when the mode select input 178 is set to logical high.

When the mode select circuit 124 receives the mode select command MOD to change to the second operation mode, the output signal SIG_OUT from the final frequency divider 126 is supplied at the selecting clock signal output 176 to provide a select clock signal SCLK. Advantageously, the mode select circuit 124 is configured not to switch until a rising edge is received at the clock signal input 174. This ensures that the select clock signal SCLK will start with a full cycle.

In the phase selector 122, the select clock signal SCLK is received via the select clock signal input 138 and is used to generate a clock signal CLK_SYN for triggering the cycle shift register 166 in the control circuit 160. Thus, the logical high state in the cycle shift register 166 is cyclically shifted with the clock of the output signal SIG_OUT and the control signals ENI, ENQ, ENIN, ENQN will control the signal multiplexer 140 to cyclically switch through the metasignals META_{I}, META_{Q}, META_{IN} and META_{QN}. This means that every four periods of the intermediate output signal DIV4_{—}5, the signal multiplexer 140 switches from one metasignal METAₖ to the next metasignal METAₖ+1 whose phase is 90° behind the phase of the first signal. As a result, after 16 periods of the input signal SIG_IN, one period is suppressed or “swallowed” since the frequency of the metasignals is ¼ of the frequency of the input signal SIG_IN. As a result, the prescaler 110 now performs a division of the input signal SIG_IN with a dividing factor of v′=17 as desired.

To avoid the generation of glitches, the signal multiplexer 140 is controlled to switch from one metasignal METAₖ to another METAₖ₊₁ only when both metasignals are in the same logical state. This condition is fulfilled if the clock signal CLK_SYN for triggering the cycle shift register 166 is synchronized with the metasignals META_{I}, META_{Q}, META_{IN} and META_{QN} themselves. For this purpose, the clock multiplexer 150 provides at its clock sync output 156 a clock sync signal SYNC for the control circuit 160. This clock sync signal SYNC is received at the enable input 169a of the trigger unit 169. At the clock input 169b, the trigger unit 169 receives the select clock signal SCLK from the mode select circuit 124. The state of the select clock signal SCLK is switched through when a rising edge of the clock sync signal SYNC occurs to pass the trigger signal CLK_SYN to the cycle shift register 166. Since the period of the select clock signal SCLK is four times longer than the period of the clock sync signal SYNC, the trigger signal CLK_SYN is reliably synchronized with the clock sync signal SYNC.

The synchronization has to be dynamic, i.e. when the signal multiplexer 140 has switched to another metasignal, the select clock signal SCLK has to be adapted too. Therefore, the select inputs 154a, 154b, 154c, 154d of the clock multiplexer 150 are connected to the control circuit 160 to receive the control signals ENI, ENQ, ENIN, ENQN just like the select inputs 144I, 144Q, 144IN, 144QN of the signal multiplexer 140, but in a different order.

Namely, a control output of the control circuit 160 is on the one hand connected to a select input of the signal multiplexer 140 which is assigned to a specific source input of the signal multiplexer 140, and the same control output of the control circuit 160 is on the other hand connected to a select input of the clock sync multiplexer 150 which is assigned to a specific source input of the clock sync multiplexer 150. Then, if the source input of the signal multiplexer 140 is connected to a first metasignal META₁, the source input of the clock sync multiplexer 150 is connected to a second metasignal META₂ having a phase which is 90° ahead with respect to the phase of the first metasignal META₁.

For example, in FIG. 6, the metasignal META_{Q} at source input 142Q of the signal multiplexer 140 is selected after T₁ to represent the intermediate signal DIV4_{—}5. This means that ENQ at the assigned source input I42Q of the signal multiplexer 140 is high. ENQ is also connected to the select input 154b of the clock multiplexer 150 via the delay line 158b. Therefore, from the assigned source input 154b of the clock multiplexer 150, the metasignal META_{I}, which has a phase shift of 90° ante with respect to the metasignal META_{Q} is momentarily chosen for clock sync signal SYNC at the clock sync output 156. As a result, the clock signal CLK_SYN is synchronized with the metasignal META_{I} to trigger the cycle shift register 166 for controlling the signal multiplexer 140 to switch from metasignal META_{Q} to META_{IN}.

Advantageously, delay lines 158a, 158b, 158c, 158d are provided at the control source inputs 154a, 154b, 154c, 154d of the clock multiplexer 150 to compensate for propagation times in the signal paths.

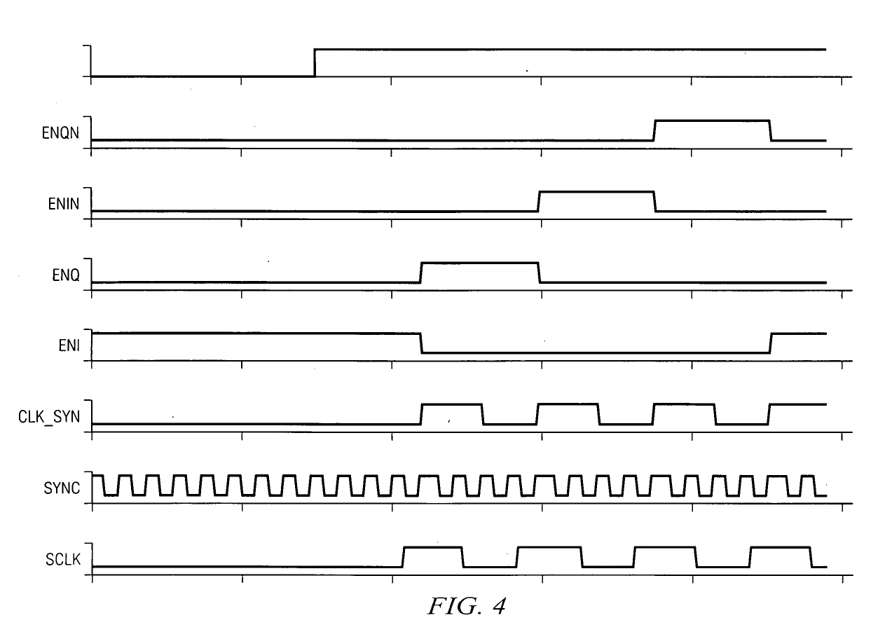

FIGS. 4 to 6 show graphs illustrating a selection from the metasignals META_{I}, META_{Q}, META_{IN} and META_{QN}, the control signals ENI, ENQ, ENIN, ENQN, the intermediate signal DIV4_{—}5 as well as the clock and sync signals SCLK, SYNC and CLK-SYN. FIG. 4 illustrates signals when the prescaler 110 switches from the first to the second mode, FIG. 5 illustrates signals when the prescaler operates in the second mode and FIG. 6 illustrates the synchronized glitch-free switching from META_{I} to META_{Q} (ref. T₁), and from META_{Q} to META_{IN} (ref. T₂).

Of course, the prescaler can be configured to operate in more than two modes to provide more than two different dividing factors.

Although the present invention and its advantages have been described in detail, it should be understood that various changes, substitutions and alterations can be made herein without departing from the spirit and scope of the invention as defined by the appended claims.

What is claimed is:

1. A prescaler for use in a phase locked loop circuit, comprising:
a signal input receiving a digital input signal and a signal output supplying a digital output signal,
a phase shifter receiving an input signal from said signal input, and supplying a set of n metasignals each having a relative phase shift of 2π/n with respect to another one of said metasignals,
a phase selector having n inputs to each of which is applied a different one of said metasignals and an output supplying a selected one of said metasignals,
a final frequency divider having an input connected to the output of the phase selector and an output forming said signal output of the prescaler,
and a control circuit associated with said phase selector and controlling said phase selector so that the output of the phase selector is switched between different metasignals only when said different metasignals are in the same logical state.

2. The prescaler of claim 1, wherein the phase shifter includes an initial frequency divider receiving said input signal from said signal input and dividing said input signal by an initial dividing factor p, p being an integer number.

3. The prescaler of claim 1, wherein said phase selector can operate in a first mode to select continuously a particular one of said metasignals for propagation to its output.

4. The prescaler of claim 3, wherein the phase shifter includes an initial frequency divider receiving said input signal from said signal input and dividing said input signal by an initial dividing factor p, p being an integer number.

5. The prescaler of claim 3, wherein said phase selector can operate in a second mode in which the signal output is connected to a clock input of said control circuit and the control circuit controls the phase selector to cyclically select each of the metasignals under control of said output signal (SIG_OUT).

6. The prescaler of claim 5, wherein the phase shifter includes an initial frequency divider receiving said input signal from said signal input and dividing said input signal by an initial dividing factor p, p being an integer number.
